(19) United States
(12) Patent Application Publication
(10) Pub. No.: US 2022/0157598 A1
(43) Pub. Date: May 19, 2022

(54) METHOD FOR FORMING FILM AND MANUFACTURING SEMICONDUCTOR DEVICE

(71) Applicants: DENSO CORPORATION, Kariya-city (JP); National University Corporation Kyoto Institute of Technology, Kyoto-shi (JP)

(72) Inventors: Tatsuji NAGAOKA, Toyota-shi (JP); Hiroyuki NISHINAKA, Kyoto-shi (JP); Masahiro YOSHIMOTO, Kyoto-shi (JP); Daisuke TAHARA, Kyoto-shi (JP)

(21) Appl. No.: 17/591,002

(22) Filed: Feb. 2, 2022

Related U.S. Application Data
(63) Continuation of application No. PCT/JP2020/000539, filed on Jan. 9, 2020.

(30) Foreign Application Priority Data
Sep. 2, 2019 (JP) PCT/JP2019/034436

(51) Int. Cl. H01L 21/02

(52) U.S. Cl. CPC H01L 21/0257; H01L 21/02414; H01L 21/02565; H01L 21/02554

(57) ABSTRACT

A method for forming a semi-conductive or conductive oxide film is provided. The oxide film is doped with a bismuth and made of an indium oxide, an aluminum oxide, a gallium oxide, an oxide including the gallium oxide, or an oxide of a combination thereof. The method includes supplying a mist of a solution to a surface of the substrate while heating the substrate. An oxide film material and a bismuth compound being dissolved in the solution. The bismuth compound is selected from the group consisting of bismuth ethoxide, bismuth acetate oxide, bismuth acetate, bismuth nitrate pentahydrate, bismuth nitrate, bismuth oxynitrate, bismuth 2-ethylhexanoate, bismuth octanoate, bismuth naphthenate, bismuth subgallate, bismuth subsalicylate, bismuth chloride, bismuth oxychloride, bismuth citrate, bismuth oxyacetate, bismuth oxide perchlorate, bismuth oxysalicylate, bismuth bromide, bismuth iodide, bismuth hydroxide, bismuth oxycarbonate, bismuth sulfide, bismuth sulfate, bismuth carbonate, and bismuth oxide.

### CROSS REFERENCE TO RELATED APPLICATION

The present application is a continuation application of International Patent Application No. PCT/JP2020/000539 filed on Jan. 9, 2020, which designated the U.S. and claims the benefit of priority from International Patent Application No. PCT/JP2019/034436 filed on Sep. 2, 2019. The entire disclosures of all of the above applications are incorporated herein by reference.

### TECHNICAL FIELD

The techniques disclosed herein relate to techniques for forming a film on a substrate.

### BACKGROUND

An oxide film that is semi-conductive or conductive is formed on the surface by supplying a mist of a solution in which an oxide film material is dissolved to the surface of the substrate while heating the substrate.

### SUMMARY

An oxide film that is semi-conductive or conductive and is doped with bismuth is formed on a substrate. This film forming method includes supplying a mist of a solution to the surface of the substrate while heating the substrate. An oxide film material containing a constituent element of the oxide film and a bismuth compound are dissolved in the solution. The bismuth compound is selected from the group consisting of bismuth ethoxide, bismuth acetate oxide, bismuth acetate, bismuth nitrate pentahydrate, bismuth nitrate, bismuth oxynitrate, bismuth 2-ethylhexanoate, bismuth octanoate, bismuth naphthenate, bismuth subgallate, bismuth subsalicylate, bismuth chloride, bismuth oxychloride, bismuth citrate, bismuth oxyacetate, bismuth oxide perchlorate, bismuth oxysalicylate, bismuth bromide, bismuth iodide, bismuth hydroxide, bismuth oxycarbonate, bismuth sulfide, bismuth sulfate, bismuth carbonate, and bismuth oxide.

### BRIEF DESCRIPTION OF DRAWINGS

FIG. 1 is a configuration diagram of a film forming apparatus 10.

FIG. 2 is a graph showing concentration distribution of bismuth in a formed gallium oxide film.

### DESCRIPTION OF EMBODIMENTS

To begin with, examples of relevant techniques will be described.

A technique for forming an oxide film that is semi-conductive or conductive on the surface of a substrate has been known. In this technique, a mist of a solution in which an oxide film material is dissolved is supplied to the surface of the substrate while heating the substrate. According to this technique, an oxide film can be grown on the surface of the substrate.

By doping an oxide film that is semi-conductive or conductive with bismuth, the characteristics of the oxide film can be changed. However, in the technique of forming an oxide film by supplying mist to the surface of a substrate, a method of doping the oxide film with bismuth has not been established. This specification proposes a technique for doping an oxide film with bismuth when forming the oxide film by supplying mist to the surface of a substrate.

With the film forming method disclosed herein, an oxide film that is semi-conductive or conductive and is doped with bismuth is formed on a substrate. This film forming method includes supplying a mist of a solution to the surface of the substrate while heating the substrate. An oxide film material containing a constituent element of the oxide film and a bismuth compound are dissolved in the solution. The bismuth compound is selected from the group consisting of bismuth ethoxide, bismuth acetate oxide, bismuth acetate, bismuth nitrate pentahydrate, bismuth nitrate, bismuth oxynitrate, bismuth 2-ethylhexanoate, bismuth octanoate, bismuth naphthenate, bismuth subgallate, bismuth subsalicylate, bismuth chloride, bismuth oxychloride, bismuth citrate, bismuth oxyacetate, bismuth oxide perchlorate, bismuth oxysalicylate, bismuth bromide, bismuth iodide, bismuth hydroxide, bismuth oxycarbonate, bismuth sulfide, bismuth sulfate, bismuth carbonate, and bismuth oxide.

By supplying the mist of the solution containing the bismuth compound selected from the above group to the surface of the substrate, the oxide film doped with bismuth can be formed on the substrate.

The additional features of a method for forming a film disclosed herein are listed below. In addition, each feature listed below is useful independently.

In one example of the method for forming a film disclosed in the present specification, the bismuth compound may be a basic bismuth compound. For example, the bismuth compound may be basic bismuth acetate, basic bismuth sulfate, basic bismuth nitrate, or basic bismuth carbonate.

Since the basic bismuth compound easily dissolves in a solution, the concentration of bismuth in the solution can be increased. Therefore, by using the basic bismuth compound, an oxide film having a high bismuth content can be grown.

In one example of the method for forming a film disclosed in the present specification, the step of supplying, to the surface of the substrate, a mist of a solution in which the oxide film material and the bismuth compound are dissolved may include a step of generating the mist from the solution in which both the oxide film material and the bismuth compound are dissolved and a step of supplying, to the surface of the substrate, the mist of the solution in which both the oxide film material and the bismuth compound are dissolved.

In another example of the method for forming a film disclosed in the present specification, the step of supplying, to the surface of the substrate, the mist of the solution in which the oxide film material and the bismuth compound are dissolved may include a step of generating a mist from a solution in which the oxide film material is dissolved, a step of generating a mist from a solution in which the bismuth compound is dissolved, and a step of supplying, to the surface of the substrate, the mist of the solution in which the oxide film material is dissolved and the mist of the solution in which the bismuth compound is dissolved.

In this way, by using either the method of generating the mist from the solution in which both the oxide film material and the bismuth compound are dissolved, or the method of generating mist from each of the solution in which the oxide film material is dissolved and the solution in which the bismuth compound is dissolved, an oxide film can be suitably formed.

In one example of the method for forming a film disclosed in the present specification, the oxide film may be a single crystal film.

By forming an oxide film which is a single crystal, the oxide film can be suitably used for a semiconductor device or the like.

In one example of the method for forming a film disclosed in the present specification, the oxide film may be made of indium oxide, aluminum oxide, gallium oxide, or an oxide of a combination thereof. In this case, the oxide film material may contain at least one of an indium compound, an aluminum compound, and a gallium compound.

In one example of the method for forming a film disclosed in the present specification, the oxide film may be made of zinc oxide. In this case, the oxide film material may contain a zinc compound.

In one example of the method for forming a film disclosed in the present specification, the oxide film may be made of gallium oxide or an oxide containing gallium oxide. In this case, the oxide film material may be a gallium compound.

In one example of the method for forming a film disclosed in the present specification, the gallium compound may be an organic compound.

In one example of the method for forming a film disclosed in the present specification, the gallium compound may be a metal complex.

In one example of the method for forming a film disclosed in the present specification, the gallium compound may be gallium acetylacetonate.

In one example of the method for forming a film disclosed in the present specification, the gallium compound may be a halide.

In one example of the method for forming a film disclosed in the present specification, the gallium compound may be gallium chloride.

Gallium chloride is inexpensive and less likely to generate residual impurities. Therefore, it is useful as an oxide film material.

In an example of the method for forming a film disclosed in the present specification, the number of bismuth atoms contained in the mist of the solution in which the oxide film material and the bismuth compound are dissolved may be less than or equal to 1000 times the total number of indium atoms, aluminum atoms, and gallium atoms in the mist in which the oxide film material and the bismuth compound are dissolved.

According to this configuration, an oxide film having high crystal quality can be formed.

In one example of the method for forming a film disclosed in the present specification, the substrate may be made of gallium oxide.

In one example of the method for forming a film disclosed in the present specification, the substrate may be made of β-Ga₂O₃.

In one example of the method for forming a film disclosed in the present specification, the substrate may be made of α-Ga₂O₃.

In one example of the method for forming a film disclosed in the present specification, the substrate may be made of α-Al₂O₃.

In one example of the method for forming a film disclosed in the present specification, the oxide film may be made of β-Ga₂O₃.

According to this configuration, the characteristics of the oxide film are stable, and the conductivity of the oxide film can be easily controlled.

In one example of the method for forming a film disclosed in the present specification, the oxide film may be a semiconductor film. The method for forming the film may include doping the oxide film with an acceptor. The step of supplying the mist and the step of doping the oxide film with the acceptor may be performed at the same time. That is, the growing oxide film may be doped with the acceptor while supplying the mist. Alternatively, after the oxide film has been formed, a step of doping the oxide film with the acceptor may be performed.

The acceptor can be activated in the oxide semiconductor film containing bismuth. Therefore, a p-type oxide semiconductor film can be formed.

In one example of the method for forming a film disclosed in the present specification, the substrate may be heated within a range between 400 and 1000° C. when forming the oxide film.

According to this configuration, an oxide film having high crystal quality can be formed, and the conductivity of the oxide film can be accurately controlled.

When the bismuth compound is bismuth oxide, an acid selected from the group consisting of hydrochloric acid, nitric acid, sulfuric acid, and acetic acid may be added to the solution.

According to this configuration, bismuth oxide easily dissolves in the solution.

### Embodiment

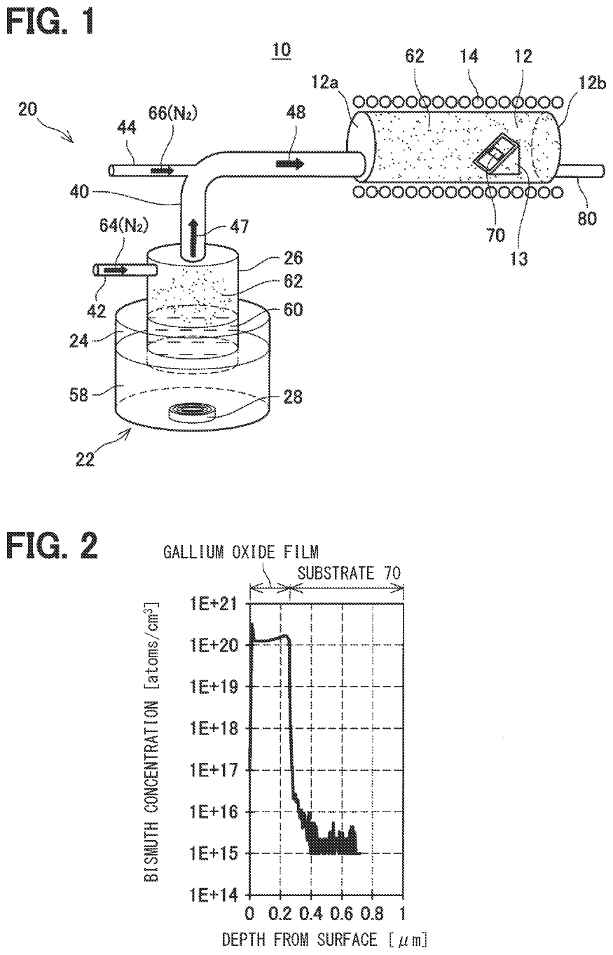

A film forming apparatus 10 shown in FIG. 1 is an apparatus for forming an oxide film on a substrate 70. The film forming apparatus 10 includes a furnace 12 inside which the substrate 70 is arranged, a heater 14 for heating the furnace 12, a mist supplying device 20 connected to the furnace 12, and an exhaust pipe 80 connected to the furnace 12.

The specific configuration of the furnace 12 is not particularly limited. As an example, the furnace 12 shown in FIG. 1 is a tube furnace extending from the upstream end 12a to the downstream end 12b. The cross-section of the furnace 12 perpendicular to the longitudinal direction of the furnace 12 has a circular shape. For example, the diameter of the furnace 12 is about 40 mm. However, the shape of the cross-section of the furnace 12 is not limited to a circular shape.

The mist supplying device 20 is connected to the upstream end 12a of the furnace 12. The exhaust pipe 80 is connected to the downstream end 12b of the furnace 12. The mist supplying device 20 supplies a mist 62 into the furnace 12. The mist 62 supplied into the furnace 12 by the mist supplying device 20 flows through the furnace 12 to the downstream end 12b, and then is discharged out of the furnace 12 through the exhaust pipe 80.

The furnace 12 includes therein a substrate stage 13 for supporting the substrate 70. The substrate stage 13 is configured such that the substrate 70 is tilted with respect to the longitudinal direction of the furnace 12. The substrate 70 supported by the substrate stage 13 is arranged such that the mist flowing through the furnace 12 from the upstream end 12a toward the downstream end 12b hits the surface of the substrate 70.

The heater 14 heats the furnace 12 as described above. The specific configuration of the heater 14 is not particularly limited. As an example, the heater 14 shown in FIG. 1 is an electric heater and is arranged along the outer circumferential wall of the furnace 12. As a result, the heater 14 heats the outer circumferential wall of the furnace 12, thereby heating the substrate 70 in the furnace 12.

The mist supplying device 20 has a mist generating tank 22. The mist generating tank 22 has a water tank 24, a solution storage tank 26, and an ultrasonic vibrator 28. The water tank 24 is a container opening at an upper part, and water 58 is stored therein. The ultrasonic vibrator 28 is disposed on the bottom surface of the water tank 24. The ultrasonic vibrator 28 applies ultrasonic vibration to the water 58 in the water tank 24. The solution storage tank 26 is a closed container. The solution storage tank 26 stores a solution 60 containing a raw material of a film to be epitaxially grown on the surface of the substrate 70. Further, the solution 60 may include a raw material (e.g., ammonium fluoride or the like) for imparting an n-type or p-type dopant to the film. The bottom of the solution storage tank 26 is immersed in the water 58 in the water tank 24. The bottom surface of the solution storage tank 26 is formed of a film. As a result, ultrasonic vibration is easily transmitted from the water 58 in the water tank 24 to the solution 60 in the solution storage tank 26. When the ultrasonic vibrator 28 applies ultrasonic vibration to the water 58 in the water tank 24, the ultrasonic vibration is transmitted to the solution 60 via the water 58. Then, the surface of the solution 60 vibrates, and the mist 62 of the solution 60 is generated in the space above the solution 60 (i.e., the space in the solution storage tank 26).

The mist supplying device 20 further includes a mist supply passage 40, a carrier gas supply passage 42, and a dilution gas supply passage 44. The mist supply passage 40 fluidly connects between the solution storage tank 26 and the furnace 12. The carrier gas supply passage 42 is fluidly connected to the solution storage tank 26. The dilution gas supply passage 44 is fluidly connected to the mist supply passage 40. The carrier gas supply passage 42 supplies a carrier gas 64 to the solution storage tank 26. The dilution gas supply passage 44 supplies a dilution gas 66 to the mist supply passage 40.

### First Embodiment

Next, a method for forming a film using the film forming apparatus 10 will be described. In the first embodiment, as the substrate 70, a substrate made of a single crystal of β-type gallium oxide (β-Ga₂O₃) is used. In the single crystal of β-Ga₂O₃, (010) crystal plane is exposed on the surface. Further, in the first embodiment, a β-type gallium oxide film is formed on the surface of the substrate 70. Further, in the first embodiment, as the solution 60, an aqueous solution in which gallium chloride (GaCl₃ or Ga₂Cl₆) and basic bismuth nitrate (4BiNO₃(OH)₂.BiO(OH)) are dissolved is used. Gallium chloride is a raw material for a gallium oxide film. Basic bismuth nitrate supplies bismuth for doping the gallium oxide film. That is, in the first embodiment, the oxide film is a β-type gallium oxide film, the oxide film material is gallium chloride, and the bismuth compound is basic bismuth nitrate. In the solution 60, the gallium chloride is dissolved at a concentration of 0.5 mol/L, and the basic bismuth nitrate is dissolved at a concentration of 0.01 mol/L. Further, in the first embodiment, nitrogen gas is used as the carrier gas 64 and the dilution gas 66.

As shown in FIG. 1, first, the substrate 70 is installed on the substrate stage 13 in the furnace 12. Here, the substrate 70 is arranged on the substrate stage 13 such that the (010) crystal plane of the substrate 70 faces upward to be exposed to the mist 62. Next, the substrate 70 is heated by the heater 14. Here, the temperature of the substrate 70 is controlled at about 750° C. When the temperature of the substrate 70 stabilizes, the mist supplying device 20 is operated. That is, by operating the ultrasonic vibrator 28, the mist 62 of the solution 60 is generated in the solution storage tank 26. At the same time, the carrier gas 64 is introduced into the solution storage tank 26 through the carrier gas supply passage 42, and the dilution gas 66 is introduced into the mist supply passage 40 through the dilution gas supply passage 44. Here, the total flow rate of the carrier gas 64 and the dilution gas 66 is set to about 5 L/min. The carrier gas 64 flows into the mist supply passage 40 through the solution storage tank 26 as shown by an arrow 47. At this time, the mist 62 in the solution storage tank 26 flows into the mist supply passage 40 together with the carrier gas 64. Further, the dilution gas 66 is mixed with the mist 62 in the mist supply passage 40. Thereby, the mist 62 is diluted. The mist 62 flows toward a downstream side in the mist supply passage 40 together with the nitrogen gas (i.e., the carrier gas 64 and the dilution gas 66), and flows into the furnace 12 through the mist supply passage 40 as shown by an arrow 48. In the furnace 12, the mist 62 flows to the downstream end 12b together with the nitrogen gas and is discharged out of the furnace 12 through the exhaust pipe 80.

A part of the mist 62 flowing through the furnace 12 adheres to the surface of the heated substrate 70. Then, the mist 62 (that is, the solution 60) causes a chemical reaction on the substrate 70. As a result, β-type gallium oxide (β-Ga₂O₃) is generated on the substrate 70. Since the mist 62 is continuously supplied to the surface of the substrate 70, the β-type gallium oxide film grows on the surface of the substrate 70. According to this film forming method, a high-quality single crystal β-type gallium oxide film can be grown. Bismuth atoms in the basic bismuth nitrate are incorporated into the growing gallium oxide film. Therefore, the gallium oxide film doped with bismuth can be formed. Here, the film forming processing is performed for 60 minutes, and about 100 ml of the solution 60 is consumed to grow the gallium oxide film. The gallium oxide film grown in this way exhibits the characteristics of a semiconductor or a conductor.

FIG. 2 shows the measurement results of the concentration distribution of bismuth in the gallium oxide film formed by this method. The horizontal axis of FIG. 2 indicates the depth from the surface of the gallium oxide film, and the depth of 0 μm is the position of the surface of the gallium oxide film. As shown in FIG. 2, a range between 0 and 0.22 μm is the gallium oxide film and a range deeper than 0.22 μm is the substrate 70. As shown in FIG. 2, a concentration of bismuth higher than 1×10²⁰ atoms/cm³ was observed in the grown gallium oxide film. The bismuth concentration in the grown gallium oxide film is clearly higher than the bismuth concentration in the substrate 70. As described above, according to the method of the first embodiment, it is possible to form a gallium oxide film heavily doped with bismuth.

As described above, according to the method for forming a film in the first embodiment, a β-type gallium oxide film doped with bismuth can be formed. In particular, in the first embodiment, since the β-type gallium oxide film grows homoepitaxially on the substrate 70 made of β-type gallium oxide, a higher quality β-type gallium oxide film can be formed.

### Second Embodiment

Next, the method for forming a film of the second embodiment will be described. In the second embodiment, a substrate made of sapphire (Al₂O₃) is used as the substrate 70. Further, in the second embodiment, an α-type gallium oxide film is formed on the surface of the substrate 70. Further, in the second embodiment, as the solution 60, an aqueous solution in which gallium bromide (GaBr₃, Ga₂Br₆) and basic bismuth nitrate are dissolved is used. Gallium bromide is a raw material for a gallium oxide film. Basic bismuth nitrate supplies bismuth for doping the gallium oxide film. That is, in the second embodiment, the oxide film is an α-type gallium oxide film, the oxide film material is gallium bromide, and the bismuth compound is basic bismuth nitrate. In the solution 60, gallium bromide is dissolved at a concentration of 0.1 mol/L, and basic bismuth nitrate is dissolved at a concentration of 0.001 mol/L. Further, in the second embodiment, nitrogen gas is used as the carrier gas 64 and the dilution gas 66.

In the film forming method of the second embodiment, the substrate 70 is placed on the substrate stage 13 and the substrate 70 is heated by the heater 14 in the same manner as in the first embodiment. Here, the temperature of the substrate 70 is controlled at about 500° C. When the temperature of the substrate 70 stabilizes, the mist supplying device 20 is operated. That is, the operation of the ultrasonic vibrator 28, the introduction of the carrier gas 64, and the introduction of the dilution gas 66 are performed in the same manner as in the first embodiment. As a result, the mist 62 flows into the furnace 12, and a part of the mist 62 flowing through the furnace 12 adheres to the surface of the heated substrate 70. Then, the mist 62 (that is, the solution 60) causes a chemical reaction on the substrate 70. As a result, α-type gallium oxide (α-Ga₂O₃) is generated on the substrate 70. Since the mist 62 is continuously supplied to the surface of the substrate 70, an α-type gallium oxide film grows on the surface of the substrate 70. According to this film forming method, a high-quality single crystal α-type gallium oxide film can be grown. Bismuth atoms in the basic bismuth nitrate are incorporated into the gallium oxide film. Therefore, the gallium oxide film doped with bismuth can be formed. The gallium oxide film grown in this way exhibits the characteristics of a semiconductor or a conductor. (Third embodiment)

Next, the film forming method of the third embodiment will be described. In the third embodiment, a substrate made of glass is used as the substrate 70. Further, in the third embodiment, a zinc oxide film (ZnO) is formed on the surface of the substrate 70. Further, in the third embodiment, as the solution 60, an aqueous solution in which zinc acetate (ZnAc₂, where Ac represents an acetyl group) and basic bismuth nitrate are dissolved is used. Zinc acetate is a raw material for a zinc oxide film. Basic bismuth nitrate supplies bismuth for doping the zinc oxide film. That is, in the third embodiment, the oxide film is a zinc oxide film, the oxide film material is zinc acetate, and the bismuth compound is basic bismuth nitrate. In the solution 60, zinc acetate is dissolved at a concentration of 0.05 mol/L, and basic bismuth nitrate is dissolved at a concentration of 0.001 mol/L. Further, in the third embodiment, nitrogen gas is used as the carrier gas 64 and the dilution gas 66.

In the film forming method of the third embodiment, the substrate 70 is installed on the substrate stage 13 in the same manner as in the first embodiment. Next, the substrate 70 is heated by the heater 14. Here, the temperature of the substrate 70 is controlled at about 400° C. When the temperature of the substrate 70 stabilizes, the mist supplying device 20 is operated. That is, the operation of the ultrasonic vibrator 28, the introduction of the carrier gas 64, and the introduction of the dilution gas 66 are performed in the same manner as in the first embodiment. As a result, the mist 62 flows into the furnace 12, and a part of the mist 62 flowing through the furnace 12 adheres to the surface of the heated substrate 70. Then, the mist 62 (that is, the solution 60) causes a chemical reaction on the substrate 70. As a result, zinc oxide (ZnO) is generated on the substrate 70. Since the mist 62 is continuously supplied to the surface of the substrate 70, the zinc oxide film grows on the surface of the substrate 70. According to this film forming method, the high-quality single crystal zinc oxide film can be grown. Bismuth atoms in the basic bismuth nitrate are incorporated into the zinc oxide film. Therefore, the zinc oxide film doped with bismuth can be formed. The zinc oxide film grown in this way exhibits the characteristics of a semiconductor or a conductor.

As described in the first to third embodiments, a bismuth-doped oxide film can be formed by growing an oxide film using a mist of a solution in which an oxide film material and a bismuth compound are dissolved.

In the first and second embodiment, the number (i.e., concentration) of bismuth atoms dissolved in the solution 60 is less than or equal to 1000 times the number (i.e., concentration) of gallium atoms dissolved in the solution 60. According to this configuration, a gallium oxide film having high crystal quality can be formed. Further, in the third embodiment described above, the number (i.e., concentration) of bismuth atoms dissolved in the solution 60 is equal to or less than 1000 times the number (i.e., concentration) of zinc atoms dissolved in the solution 60. According to this configuration, a zinc oxide film having high crystal quality can be formed.

In the first to third embodiments, a gallium oxide film (Ga₂O₃) or a zinc oxide film (ZnO) was formed on the surface of the substrate 70. However, another oxide film may be formed on the surface of the substrate 70. For example, an indium oxide film (In₂O₃) or an aluminum oxide film (Al₂O₃) may be formed. Further, a film of a material in which indium oxide, aluminum oxide, and gallium oxide are combined (that is, InₓAl_{y}Ga_{z}O₃, wherein 0≤x≤2, 0≤y≤2, 0≤z≤2) may be formed. When forming an indium oxide film, an indium compound can be used as the oxide film material to be dissolved in the solution 60. When forming an aluminum oxide film, an aluminum compound can be used as the oxide film material to be dissolved in the solution 60. When forming a film of a material in which indium oxide, aluminum oxide, and gallium oxide are combined, an indium compound, an aluminum compound, and a gallium compound may be used in combination as the oxide film material to be dissolved in the solution 60. In these cases, by setting the number (i.e., the molar concentration) of bismuth atoms contained in the mist 62 to less than or equal to 1000 times the total number of indium atoms, aluminum atoms, and gallium atoms contained in the mist 62 (i.e., the total molar concentrations of indium atoms, aluminum atoms, and gallium atoms), an oxide film having high crystallinity can be formed.

Further, in the first to third embodiments described above, the substrate 70 was heated within a range between 400 and 750° C. In the film forming process, the substrate 70 can be controlled at the temperature within a range between 400 and 1000° C. By controlling the temperature in this way, the oxide film can be more preferably formed.

Further, in the first to third embodiments described above, a single crystal oxide film is formed. However, an amorphous or polycrystalline oxide film may be formed.

Further, in the first to third embodiments described above, the substrate 70 was made of β-type gallium oxide, sapphire, or glass. However, the substrate 70 may be made of other materials. By using the substrate 70 made of another material, an oxide film having characteristics different from those of the first to third embodiments can be formed. For example, the substrate 70 may be made of α-type gallium oxide (α-Ga₂O₃), γ-type gallium oxide, δ-type gallium oxide, ϵ-type gallium oxide, aluminum oxide (e.g., α-type aluminum oxide (α-Al₂O₃)), or gallium nitride (GaN). Further, the substrate 70 may be an insulator, a semiconductor, or a conductor.

Further, in the first to third embodiments described above, an oxide film was formed on the surface of the substrate 70 (i.e., a plate-shaped member). However, a member having another shape may be used as the substrate, and an oxide film may be formed on the surface of the substrate.

Further, in the first to third embodiments described above, the bismuth compound dissolved in the solution 60 is basic bismuth nitrate. However, other materials may be used as the bismuth compound to be dissolved in the solution 60. For example, as the bismuth compound to be dissolved in the solution 60, one or multiple materials selected from the group consisting of bismuth ethoxide, bismuth acetate oxide, bismuth acetate, bismuth nitrate pentahydrate, bismuth nitrate, bismuth oxynitrate, bismuth 2-ethylhexanoate, bismuth octanoate, bismuth naphthenate, bismuth subgallate, bismuth subsalicylate, bismuth chloride, bismuth oxychloride, bismuth citrate, bismuth oxyacetate, bismuth oxide perchlorate, bismuth oxysalicylate, bismuth bromide, bismuth iodide, bismuth hydroxide, bismuth oxycarbonate, bismuth sulfide, bismuth sulfate, bismuth carbonate, and bismuth oxide can be used. Since the bismuth compounds in the above group easily dissolve in water, they are suitable for a film forming method using mist. Therefore, by growing the oxide film using the mist of the solution in which the bismuth compound in the above group is dissolved, the oxide film can be doped with bismuth. Among the bismuth compounds in the above group, basic bismuth compounds (i.e., basic bismuth acetate, basic bismuth sulfate, basic bismuth nitrate, or basic bismuth carbonate) particularly easily dissolve in water. Therefore, when such basic bismuth compound is used, it is easy to increase the bismuth concentration in the solution. Therefore, by using a basic bismuth compound, an oxide film having a high concentration of bismuth can be formed.

Further, in the first to third embodiments described above, the bismuth compound dissolved in the solution 60 is basic bismuth nitrate. However, bismuth oxide (Bi₂O₃) may be used as the bismuth compound to be dissolved in the solution 60. In this case, an acid selected from the group consisting of hydrochloric acid, nitric acid, sulfuric acid and acetic acid can be added to the solution 60. Bismuth oxide is difficult to dissolve in water. However, by adding an acid selected from the above group to water, bismuth oxide easily dissolves in the water. By growing the oxide film with a mist of the solution obtained as described above (i.e., the mist in which oxide bismuth is dissolved), the oxide film can be doped with bismuth. In addition, both bismuth oxide and the acids of the above group are industrially mass-produced and easily available. Therefore, according to this method, an oxide film doped with bismuth can be easily formed.

Further, in the first and second embodiments described above, the gallium compound dissolved in the solution 60 was gallium chloride or gallium bromide. However, other materials may be used as the gallium compound to be dissolved in the solution 60. The gallium compound may be an organic compound in order to form a high-quality gallium oxide film. Moreover, the gallium compound may be a metal complex. Alternatively, the gallium compound may be a halide. For example, as the gallium compound, gallium acetylacetonate (e.g., gallium (111) acetylacetonate (C₁₅H₂₁GaO₆)), gallium triacetate (C₆H₉GaO₆), gallium iodide (GaI₃, Ga₂I₆) and the like can be used. However, gallium chloride (particularly gallium (111) chloride) is cheaper and film formation can be performed with less residual impurities. Thus, gallium chloride is easier to use.

Further, in the third embodiment described above, the zinc compound dissolved in the solution 60 is zinc acetate. However, other materials may be used as the zinc compound to be dissolved in the solution 60.

Further, in the first to third embodiments, the solution 60 in which both the oxide film material and the bismuth compound are dissolved is stored in the solution storage tank 26. The mist is generated from the solution 60 and supplied to the furnace 12. However, it is also possible to separately prepare a first container for the solution in which the oxide film material is dissolved and a second container for the solution in which the bismuth compound is dissolved. Then, the first mist may be generated from the solution in which the oxide film material is dissolved in the first container, the second mist may be generated from the solution in which the bismuth compound is dissolved in the second container, and the first mist and the second mist may be supplied to the furnace 12.

Further, in the first to third embodiments, nitrogen gas was used as the carrier gas 64 and the dilution gas 66. However, other gas such as an inert gas may be used as the carrier gas 64 and the dilution gas 66.

Further, in the first to third embodiments, the grown oxide film is not doped with an acceptor, but the oxide film may be doped with an acceptor. For example, a substance containing the acceptor is further dissolved in the solution 60 to grow the oxide film containing the acceptor. Alternatively, the oxide film may be doped with an acceptor after generating the oxide film without the acceptor. For example, after the oxide film is grown, acceptors (e.g., Mg, Cd, Zn, N, etc.) may be ion-implanted into the oxide film. Alternatively, it is also possible to form a layer containing an acceptor on the surface after the oxide film is grown and diffuse the acceptor from the layer to the oxide film by solid phase diffusion. It is difficult to activate the acceptor inside the oxide film (particularly the gallium oxide film). However, it is possible to activate acceptors inside the oxide film (particularly the gallium oxide film) containing bismuth. (See Fernado P. Sabino, Xuefen Cai, Su-Huai Wei, and Anderson Janotti (2019), “Bismuth-doped Ga₂O₃ as candidate for p-type transparent conducting material”. arXiv: 1906.00840v1). Therefore, a p-type gallium oxide film can be formed by doping an oxide film containing bismuth with an acceptor.

Further, the semiconductor device may be manufactured by forming a semiconductor element inside the oxide film formed by any of the above film forming methods.

Although the embodiments have been described in detail above, these are merely examples and do not limit the scope of claims. The techniques described in claims include various modifications of the specific examples illustrated above. The technical elements described in the present specification or the drawings exhibit technical usefulness alone or in various combinations, and are not limited to the combinations described in the claims at the time of filing. In addition, the techniques illustrated in the present specification or drawings achieve a plurality of objectives at the same time, and achieving one of the objectives itself has technical usefulness.

What is claimed is:

1. A method for forming an oxide film that is semi-conductive or conductive on a substrate, the oxide film being doped with a bismuth and made of an indium oxide, an aluminum oxide, a gallium oxide, an oxide including the gallium oxide, or an oxide of a combination thereof, the method comprising
supplying a mist of a solution to a surface of the substrate while heating the substrate, an oxide film material and a bismuth compound being dissolved in the solution, the oxide film material containing a constituent element of the oxide film, wherein
the bismuth compound is selected from the group consisting of bismuth ethoxide, bismuth acetate oxide, bismuth acetate, bismuth nitrate pentahydrate, bismuth nitrate, bismuth oxynitrate, bismuth 2-ethylhexanoate, bismuth octanoate, bismuth naphthenate, bismuth subgallate, bismuth subsalicylate, bismuth chloride, bismuth oxychloride, bismuth citrate, bismuth oxyacetate, bismuth oxide perchlorate, bismuth oxysalicylate, bismuth bromide, bismuth iodide, bismuth hydroxide, bismuth oxycarbonate, bismuth sulfide, bismuth sulfate, bismuth carbonate, and bismuth oxide.

2. The method according to claim 1, wherein
the bismuth compound is basic.

3. The method according to claim 1, wherein
the bismuth compound is a basic bismuth acetate, a basic bismuth sulfate, a basic bismuth nitrate, or a basic bismuth carbonate.

4. The method according to claim 1, wherein
supplying the mist to the surface of the substrate includes:
generating the mist from the solution in which both the oxide film material and the bismuth compound are dissolved; and
supplying, to the surface of the substrate, the mist of the solution in which both the oxide film material and the bismuth compound are dissolved.

5. The method according to claim 1, wherein
supplying the mist to the surface of the substrate includes:
generating a mist from a solution in which the oxide film material is dissolved;
generating a mist from a solution in which the bismuth compound is dissolved; and
supplying, to the surface of the substrate, the mist of the solution in which the oxide film material is dissolved and the mist of the solution in which the bismuth compound is dissolved.

6. The method according to claim 1, wherein
the oxide film is a single crystal film.

7. The method according to claim 1, wherein
the oxide film is made of the indium oxide, the aluminum oxide, the gallium oxide, or the oxide of the combination thereof, and
the oxide film material includes at least one of an indium compound, an aluminum compound, or a gallium compound.

8. The method according to claim 1, wherein
the oxide film includes a zinc oxide, and
the oxide film material includes a zinc compound.

9. The method according to claim 1, wherein
the oxide film is made of the gallium oxide or the oxide including the gallium oxide, and
the oxide film material is a gallium compound.

10. The method according to claim 9, wherein
the gallium compound is an organic compound.

11. The method according to claim 9, wherein
the gallium compound is a metal complex.

12. The method according to claim 9, wherein
the gallium compound is gallium acetylacetonate.

13. The method according to claim 9, wherein
the gallium compound is a halide.

14. The method according to claim 9, wherein
the gallium compound is gallium chloride.

15. The method according to claim 1, wherein
a number of bismuth atoms in the mist of the solution in which the oxide film material and the bismuth compound are dissolved is less than or equal to 1000 times a total number of indium atoms, aluminum atoms, and gallium atoms in the mist.

16. The method according to claim 1, wherein
the substrate is made of gallium oxide.

17. The method according to claim 16, wherein
the substrate is made of β-Ga₂O₃.

18. The method according to claim 16, wherein
the substrate is made of α-Ga₂O₃.

19. The method according to claim 1, wherein
the substrate is made of α-Al₂O₃.

20. The method according to claim 1, wherein
the oxide film is made of β-Ga₂O₃.

21. The method according to claim 1, wherein
the oxide film is a semi-conductor film, the method further comprising
doping the oxide film with an acceptor.

22. The method according to claim 1, wherein
supplying the mist of the solution to the surface of the substrate includes supplying the mist while heating the substrate at a temperature in a range between 400° C. and 1000° C.

23. The method according to claim 1, wherein
the bismuth compound is bismuth oxide, and
the solution includes an acid selected from the group consisting of hydrochloric acid, nitric acid, sulfuric acid, and acetic acid.

24. A method for producing a semiconductor device including an oxide film, the method comprising
forming the oxide film by the method according to claim 1.
